(19) United States
(12) Patent Application Publication
(10) Pub. No.: US 2016/0116562 A1
(43) Pub. Date: Apr. 28, 2016

(54) Measurement Apparatus and Measurement Method

(71) Applicant: KYUSHU UNIVERSITY, Fukuoka (JP)

(72) Inventors: Hideo UTSUMI, Fukuoka (JP); Ryoma KOBAYASHI, Fukuoka (JP)

(21) Appl. No.: 14/895,847

(22) PCT Filed: Jun. 3, 2014
(86) PCT No.: PCT/JP2014/064725

§ 371 Date: Dec. 3, 2015

Related U.S. Application Data
(60) Provisional application No. 61/830,461, filed on Jun. 3, 2013.

(51) Int. Cl. G01R 33/563; G01R 33/34; G01R 33/385

(52) U.S. Cl. CPC G01R 33/56383; G01R 33/385; G01R 33/34

(57) ABSTRACT

The measurement apparatus and the MRI apparatus are provided with a magnet, which forms a specified static magnetic field, and a magnetic field gradient coil for applying a gradient magnetic field on the static magnetic field, and the magnetic field gradient coil is a structure that is separated from the magnet and is configured to be movable relative to the magnet. The MRI apparatus is characterized in that MRI images of a subject are acquired while the magnetic field gradient coil is moving relative to the magnet.

### TECHNICAL FIELD

The present invention relates to a measurement apparatus and measurement method for obtaining a nuclear magnetic resonance (NMR: Nuclear Magnetic Resonance) signal, or further obtaining a magnetic resonance imaging (MRI: Magnetic Resonance Imaging) image.

### BACKGROUND ART

A magnetic resonance imaging device (hereinafter referred to as an MRI device) is a device for measuring a density distribution of nuclear spins and distribution of relaxation tame in a sample using the nuclear magnetic resonance phenomenon to generate and display a topographic image of the sample based. on the measurement data.

Generally, nuclear spins in the sample have precession about an axis in a direction of a main magnetic field at a frequency (Larmor frequency) determined by an intensity of the main magnetic field in a homogeneous static magnetic field (main magnetic field). When radio frequency electromagnetic waves (RF pulse) having a frequency equal to Larmor frequency are applied to the nuclear spin in this state, the nuclear spin are excited with transition to a high energy state (nuclear magnetic resonance phenomenon). Next, when the irradiation of the electromagnetic waves is stopped, the nuclear spins return to the original low energy state at e constants according to states of the nuclear spins, respectively. At this instance, a nuclear magnetic resonance signal is emitted from the atomic nucleus. This NMR signal received by a radio frequency receiving coil tuned to the frequency. It is noted that the NRM signal is also referred to as an echo signal.

Further, in the MRI device, gradient magnetic fields having three axes are applied to a space of the main magnetic field. The application of the gradient magnetic fields aims to add positional information to the detected NMR signal. A direction of the gradient corresponds to a slicing direction, an encoding direction, and a read-out direction. As a result, the MRI device can generate a two-dimensional image inside the sample by performing a two-dimensional Fourier analysis to a received echo signal train.

Incidentally, the MRI devices have been frequently used as various medical-use diagnosing devices. In addition to this, further new developments are being tried. Conventional popular MRI devices are devices for taking MRI images of samples in stationary states. On the other hand, for example, Non-patent document 1 discloses an example obtaining an MRI image of a sample being moved as a technology called TimCT (Continuous Table move). According to the TimCT technology, it is possible to obtain an MRI image of a whole body of the sample, i.e., a body from the head to the foot, of such as a patient by continuously moving a table carrying the sample in the main magnetic field of the MRI device.

Further, Patent Document 1 disclosed an example of an integrated type of MRI device featuring in that an integrated image of ESR (Electron Spin Resonance)/NMR of the sample is obtained. According to Patent Document 1, the integrated type of MRI device includes a first magnet for forming a static magnetic field for the ESR and a second magnet for forming a static magnetic field of the NMR, and a moving means for moving the sample between the static magnetic field for the ESR and the static magnetic field for the NMR. The integrated type of MRI device excite electron spins in the sample in the static magnetic field for the ESR, after t his, move the sample into the static magnetic field for the NMR to obtain the MRI image.

In such an integrated type of MRI device, an intensity of electron spin excited in the static magnetic field for the ESR can be measured as an NMR signal in which the intensity is largely amplified through so-called Overhauser effect. Accordingly, an electron spin resonance image (ESRI) with a high sensitive and a high resolution can be obtained by subtracting an MRI image of the sample generated by an ordinary NMR signal only using the static magnetic field for NMR from the MRI image of the sample generated on the basis of the NMR signal obtained as described above.

Further, when an ESR/NMR integrated type image generated by superimposing the ESR image with the MRI image based on the ordinary NMR, an intensity distribution of electron spins, etc. is visualized on the image of the sample. Since a large part of the electron spins originate from unpaired electrons of free radicals in a living body such as reactive oxygen, in such an integrated type of MRI device provides a superior advantageous effect in visualizing a redox metabolism state including free radicals closely relating to a lot of physiological phenomena and disease causes. In addition, such an integrated type of MRI devices are called an OMRI (Overhauser effect MRI) device, a PEDRI (Proton Electron Double Resonance Imaging) device, an ReMI (Redox Molecular Imaging) device, etc.

In the integrated type of MRI device disclosed in Patent document 1, the moving means carrying the sample is configured to be able to repeatedly make reciprocate movements between the static magnetic field for the ESR and a static magnetic field for the NMR to easily obtain time transition in an intensity distribution of the electron spins, i.e., a distribution of free radicals, etc. However, in the integrated MRI device, since a measurement of an NMR signal is made after stop of the sample, a large quantity of acceleration is generated when the stop is made. During this, a large load is on the living body, etc. of the sample.

Patent document 2 discloses an example of an integrated type of MRI device configured to be able to make the sample pass (relatively pass) the static magnetic field for the ESR and the static magnetic field of the NMR in such a state that the sample is kept stopping by rotationally moving the first magnet for forming the static magnetic field of the ESR and the second magnet for forming the static magnetic field of the NMR along a circular track. In the integrated type of MRI device, the problem of the load such as acceleration on the sample such as the living body because the NMR signal is measured in the state in which the sample is kept stopping.

### PRIOR ART

### Patent Document

Patent Document 1: JP2006-204551A

Patent Document 2: JP2011-527222A

Non-patent Document 1: “Step up MRI 2010-Technical development front line: Advanced technology of imaging based on MTI-TimCT-Tim”, [online], Takashi Moroi, September, 2010 [retrieved on. May 23, 2014]

internet<URL:http://www.innervision.co.jp/suite/siemens/technote/100966/>

### SUMMARY OF INVENTION

### Problem to be Solved by Invention

The MRI device using the TimCT technology disclosed in Non-Patent Document 1 can obtain an MRI image of, for example, a whole of a human being, by make the table carrying the sample pass through the main magnetic field. This is a case in which photographing the sample being moving is successfully made, which has been considered to be impossible for the ordinary MRI device. However, the MRI device has a low speed of moving the table, i.e., the sample (the moving speed is about several cm/sec, which is very lower than a NMR signal detection time), so that there is a limit to enhance a photographing speed).

Regarding this, when the moving speed of the sample is made faster to further shorten the photographing time, various problems, such as an acceleration problem to the human body, should be solved. For example, when the moving speed is high, because time for which the part to be photographed passes the homorganic region of the main magnetic field of the NMR becomes short, it is supposed that the sample has already passed a region in which homogeneity of the magnetic field of the magnet is high within a photographing sequence time period from excitation of the nuclear spin to reception of the NMR signal. In such a case, the magnetic resonance signal is disturbed, so that it becomes difficult to obtain a good MRI image.

In the integrated type of MRI disclosed in Patent Document 2, though the problem of the acceleration on the sample in the integrated type of MRI disclosed in Patent Document 1 has been solved. Instead, there are a problem of complexity in structure of a connection and feeding part to the magnetic-field gradient coil for generating a gradient magnetic field and a problem of displacement between images if center position of the gradient magnetic field coil and the sample is suitably adjusted during a photographing sequence.

The magnetic-field gradient coil includes at least three independent coils for forming gradient magnetic fields in three axial directions x, y, z by respective coils. The three coils need at least six power cables for feeding. In the integrated type of MRI disclosed in Patent Document 2, the magnetic-field gradient coil is fixed to the second magnet forming the static magnetic field for NMR in which the magnetic-field gradient coil is rotationally moved togeter with the second magnet in the same direction repeatedly. Accordingly, when the power cables are simply connected to the magnetic-field gradient coil, the power cables are twisted with rotation of the magnetic-field gradient coil. To avoid twist of the power cable, various devices become necessary for the connection and feeding part to the magnetic-field gradient coil, and the configuration of the connection and feeding part the magnetic-field gradient coil become complicated.

The present invention aims to provide a measurement apparatus and a measurement method, which can obtain a preferable MRI image though the sample or the magnet for forming the main magnetic field (static magnetic field) move at a high speed with a simple structure of the connection and feeding part the magnetic-field gradient coil, in which an adjustment of the MRI image is easy.

### Means for Solving Problem

The aim of the present invention can be achieved with a configuration which allows the magnetic-field gradient coil to be relatively movable with respect to the magnet forming the static magnetic field (main magnetic field) for the NMR. In other words, a measurement apparatus according to the present invention, includes:

a magnet forming a static magnetic field in a predetermined regional space;

a magnetic-field gradient coil applying a gradient magnetic field to the static magnetic field, the magnetic-field gradient coil so arranged to be movable relative to the magnet forming the static magnetic field; and

a resonation coil radiating a radio frequency signal that excite nuclear spins included in a sample and receiving a nuclear magnetic resonance signal caused by the nuclear spins.

In addition, in the measurement apparatus as defined above, the sample is irradiated with the radio frequency signal through the resonation coil and receives and obtains the nuclear magnetic resonance signal, while the magnetic-field gradient coil is relatively moving in the regional space in which the static magnetic field is formed.

### Advantageous Effect of Invention

According to the present invention, the MRI image can be obtained though the sample or the magnet forming the main magnetic field (static field) moves at a high speed and a connection and feeding part for the magnetic-field gradient coil can be made simple. Further, a relation between the configuration of the invention and its advantageous effect is described in detailed in the description of embodiments.

### BRIEF DESCRIPTION OF DRAWINGS

FIG. 1 is a schematically illustrating an example of a sectional structure viewed from a lateral direction of an MRI device for photographing a whole body of a sample according to a first embodiment of the present invention.

FIG. 2 illustrates an example of a sectional configuration viewed from a front of the MRI device for photographing the whole of the body of the sample according to the first embodiment of the present invention.

FIG. 3 is an example of a top view of the MRI device for photographing the whole of the body of the sample according to the first embodiment of the present invention.

FIG. 4 is a drawing schematically illustrating an example of a perspective view of an ESR/NMR integrated type of MRI device according to a second embodiment of the present invention.

FIG. 5 is a drawing illustrating an example of a top view of the ESR/NMR integrated type of MRI device according to the second embodiment of the present invention.

FIG. 6 is a drawing illustrating an example of a cross-sectional structure viewed from a lateral direction of the ESR/NMR integrated type of MRI device according to the second embodiment of the present invention.

FIG. 7 is a drawing illustrating a position at which a magnetic-field gradient coil is disposed in the ESR/NMR integrated type of MRI device according to the second embodiment of the present invention.

FIG. 8 is a drawing drawing illustrating an MRI image obtained by the ESR/NMR integrated type of MRI device according to the second embodiment of the present invention with reference to an MITI image obtained by a conventional MRI device.

### MODES FOR CARRYING OUT INVENTION

Hereinafter, embodiments of the present invention are described in detail with reference to drawings.

### FIRST EMBODIMENT

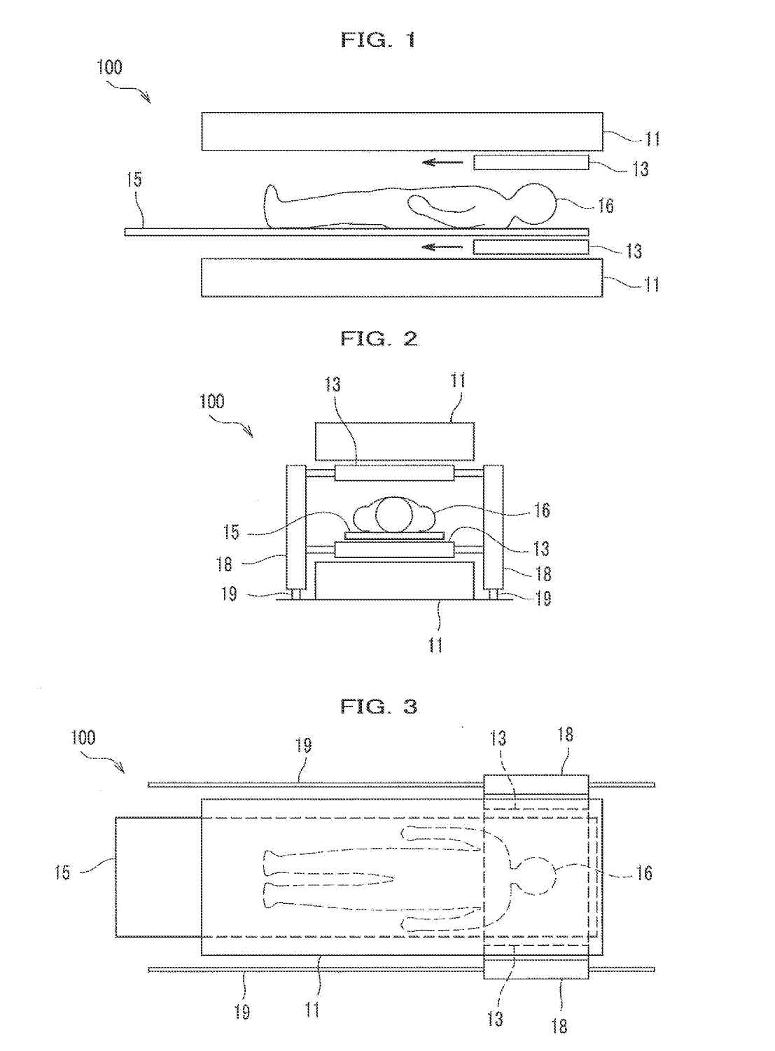

FIG. 1 is a schematically illustrating an example of a sectional structure viewed from a lateral direction of an MRI device 100 for photographing a whole body of a sample according to a first embodiment of the present invention. FIG. 2 illustrates an example of a sectional configuration viewed from a front of the MRI device 100. FIG. 3 is an example of a top view of the MRI device.

As illustrated in FIGS. 1, 2, and 3, an MRI device 100 for photographing a whole body of a sample according to the first embodiment is an MRI device of a so-called open type. Accordingly, a main magnetic field for NMR is formed in a space sandwiched between two magnets 11 vertically spaced each other and generally horizontally extends. A sample 16 as a test subject is inserted into the space where the main magnetic field is formed in such a state that the sample 16 is placed on a table 15.

A size of the space of the main magnetic field formed by the two vertically arranged magnets 11 is assumed to be so sufficiently large as to accommodate a whole of the table 15 and the sample 16. The sample 16 is inserted into the space of the main magnetic field such that an axis of the body of the sample 16 is aligned with a longitudinal direction of the two horizontally arranged magnets 11.

Further, magnetic-field gradient coils 13 are disposed at spaces between the two magnets 11 vertically arranged and the sample 16, respectively. The two magnetic-field gradient coils 13, which are vertically arranged, are fixed and connected to each other and configured to be movable in a front-rear direction along the longitudinal direction of the magnets 11 (axial direction of the body of the sample 16). In the space sandwiched between the two magnetic-field gradient coils 13 vertically arranged (the space into which the sample 16 is inserted), gradient magnetic fields are appropriately generated in an x direction, a y direction, or a z direction in a photographing sequence from when the electron nuclear spin is excited to when the NMR signal is received.

A mechanism for moving the two magnetic-field gradient coils 13 which are vertically arranged, along the longitudinal direction of the sample 16 can be provided using a cart 18 travelling on two rails 19 disposed along the longitudinal direction of the magnet 11 on floor spaces on both sides of the lower magnet 11. In this case, the two magnetic-field gradient coils 13, which are vertically arranged, are firmly supported by the two carts 18 and movable in the front-rear direction as the two carts 18 are travelling.

None of FIGS. 1 to 3 illustrate, a resonation coil for generating a radio frequency signal (electromagnetic waves) for exciting the nuclear spin included the sample (the sample 16) and receiving the resonance signal (magnetic resonance signal: NMR signal) by the nuclear spin, is fixed to and mounted on the magnetic-field gradient coil 13. In other words, the resonation coil (not shown) is moved integrally with the magnetic-field gradient coil 13.

Next, using the MRI device 100 for photographing the whole body of the sample configured as descrive above, a procedure is described to obtain the MRI image of the whole body, i.e., a body from the head to the foot of the sample. MRI devices 100 includes a not-shown control device which performs control for moving the carts 18, i.e., the magnetic-field gradient coil 13, control for allowing a current to flow through the magnetic-field gradient coil 13 to form the gradient magnetic fields, and control for outputting a radio frequency signal from a resonance coil (not shown) and receiving the NMR signal, etc.

First, the sample 16 placed on the table 15 is inserted into the main magnetic field space sandwiched between the two magnets 11 vertically arranged. After this, MRI photographing the whole body of the sample 16 is made in static states of the table 15 and the sample 16. During this, first, the control device shifts the magnetic-field gradient coil 13 to one end of the main magnetic field space sandwiched between the two magnetic-field gradient coils 13, which are vertically arranged, by driving the carts 18 (for example, an end on a side of the head of the sample 16). Next, the control device instructs the carts 18 to travel to the other end of the main magnetic field at a constant speed as well as repeatedly instructs the magnetic-field gradient coil 13 to generate the radio frequency signal, the gradient magnetic fields, and receive the NMR signal based on a predetermined photographing sequence.

In other words, the control device repeatedly performs the predetermined photographing sequence while the magnetic-field gradient coil 13 and the resonation coil are moved in the homogeneous main magnetic field. Accordingly, the control device can obtain the MRI image of the sample 16 which is sliced near a center position of the magnetic-field gradient coil 13, whenever the photographing sequence is performed.

Incidentally, in the general conventional MRI device, the magnetic-field gradient coil is configured to be integral with the magnet forming the main magnetic field. Accordingly, such a configuration has not been assumed that a magnetic-field gradient coil is separated from the magnet forming the main magnetic field. and independently moved from the magnet. This is because the magnetic-field gradient coil also serves as a role of enhancing homogeneity of the magnetic field called the shim adjustment. In other words, when the magnetic-field gradient coil is moved relative to the magnet for forming the main magnetic field, though the magnetic field is adjusted to enhance the homogeneity by the shim adjustment at a certain relative position, the adjustment becomes ineffective and a re-adjustment becomes necessary, when the relative position is varied. Further, according to the Faraday's law of electromagnetic induction, when a magnetic flux interlinking with the magnetic-field gradient coil varies, an induction current is generated, which may become a noise source.

In contrast to the conventional common sense, in this embodiment, the magnetic-field gradient coil 13 is made as a structural body separated from the magnet 11 forming the main magnetic field and movable along the longitudinal direction of the magnet 11 in the front-rear direction. In other words, the MRI device 100 according to the present embodiment is configured to leave the magnets 11 and the sample 16 in a static state, instead, move the magnetic-field gradient coil 13, which provides the MRI image of the whole body of the sample 16 essentially moving, i.e., relatively moving. According to a preliminary experiment by the inventors, though the magnetic-field gradient coil 13 is traveled at a high speed, a preferable MRI image was obtained to a practically usable extent.

In addition, in the present embodiment, the MRI image can be obtained by moving the magnetic-field gradient coil 13 at a high speed, which image is substantially the same as the MRI image made while the sample 16 is moved at a high speed. Accordingly, there is no problem in that the sample 16 receives an acceleration force. Further, there is no problem of twisted power cable connected to the magnetic-field gradient coil 13.

Further, in this embodiment, one cycle of obtaining the signal is made smaller than tens milliseconds by adjusting photographing parameters from when the nuclear spin is excited to when the NMR signal is received. Accordingly, though the magnetic-field gradient coil 13 was moved at an extremely high speed, for example, several meters per second, it is possible to obtain the NMR signal, so that it has become possible to obtain the MRI image which is practically usable.

Further, it is possible to photograph a part to be photographed at a center of FOV providing a high sensitivity, because it is possible to align the magnetic-field gradient coil 13, defining a center position of the FOV, to a center of the part of the sample to be photographed.

### Second Embodiment

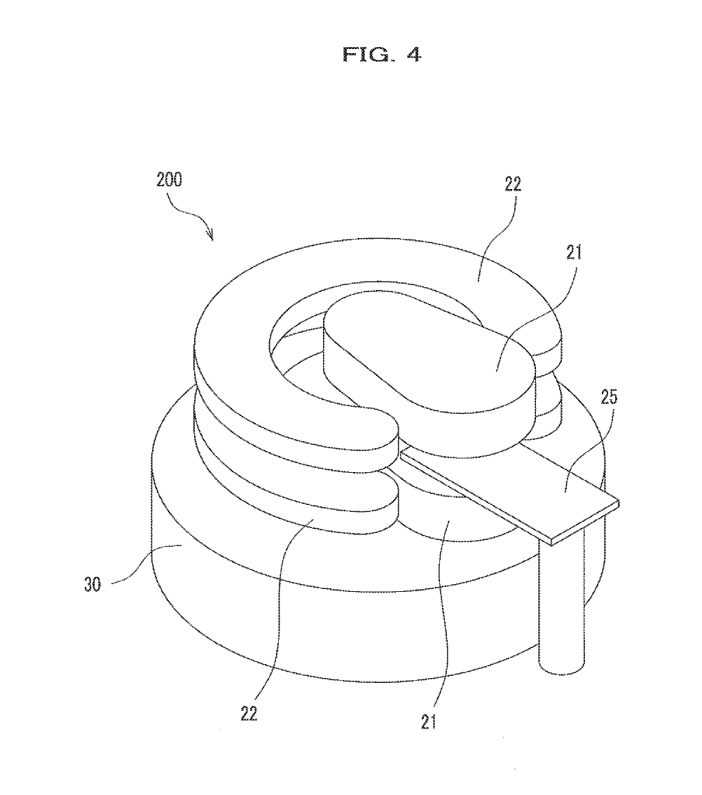

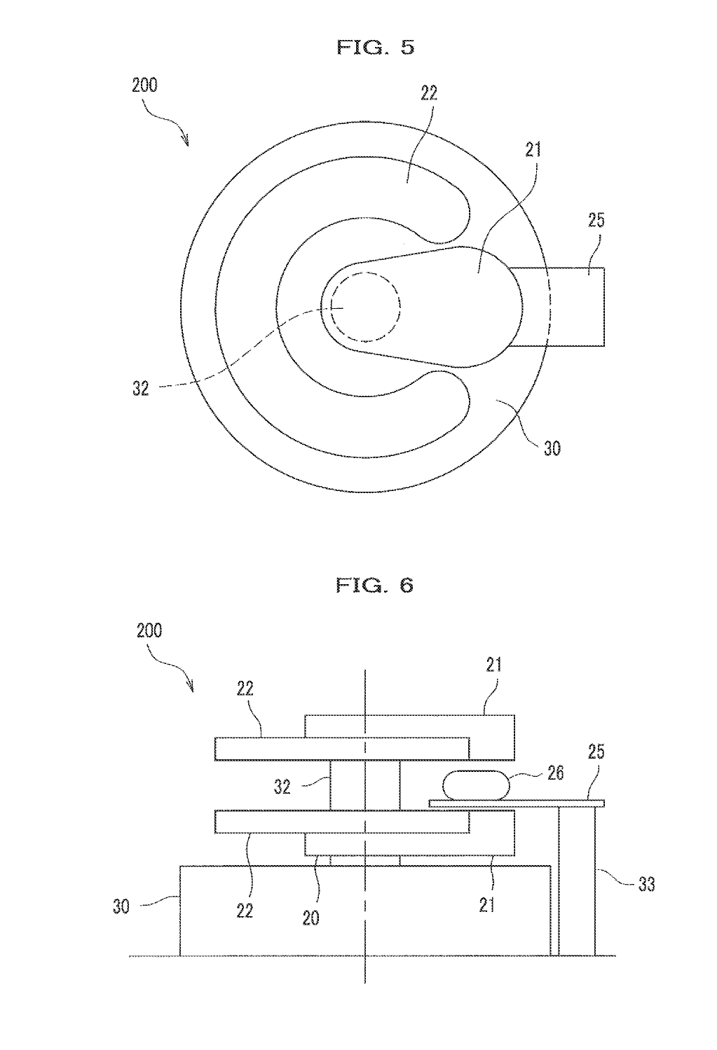

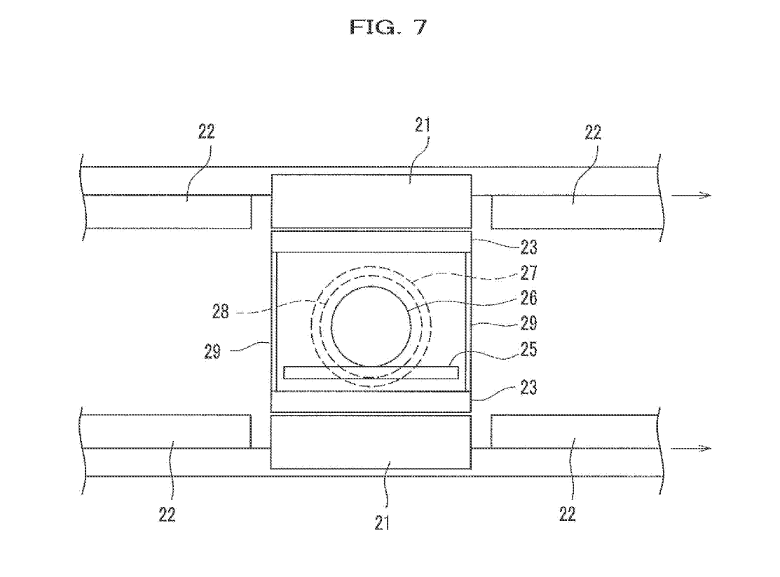

FIG. 4 is a drawing schematically illustrating an example of a perspective view of an ESR/NMR, integrated type of MRI device 200 according to a second embodiment of the present invention. FIG. 5 is a drawing illustrating an example of a top view of the ESR/NMR integrated type of MRI device 200 according to the second embodiment of the present invention. FIG. 6 is a drawing illustrating an example of a cross-sectional structure viewed from a lateral direction of the ESR/NMR integrated type of MRI device 200 according to the second embodiment of the present invention. FIG. 7 is a drawing illustrating a position at which a magnetic-field gradient coil is disposed in the ESR/NMR integrated type of MRI device 200 according to the second embodiment of the present invention. In addition, it is assumed that an ESR/NMR integrated type MRI device 200 is used for a study of Redox metabolism including reactive oxygen or free radical (fee radical) in a part, etc. of a small animal or a human body.

As shown in FIGS. 4 to 7, in the ESR/NMR integrated type MRI device 200 according to the second embodiment, two first magnets 21, which are vertically separated, and two second magnets 22, which are vertically separated, are disposed at an upper part of a base 30 formed in a circular pillar having an upper face extending in substantially horizontal. Both two first magnets 21 and the two second magnets 22, which are vertically arranged, are integrally fixed to a rotation pillar 32 coaxially arranged with a center axis of the base 30 through a supporting member (not shown). Accordingly, when the rotation pillar 32 rotates, the first magnets 21 and the second magnets 22 rotate together with the rotation pillar 32. Accordingly, when points included in upper faces of the first magnets 21 and the second magnets 22 are projected on an upper face of the base 30, the projected points draw circular tracks.

In this embodiment, at the space sandwiched between the two first magnets 21, a static magnetic field (main magnetic field) of, for example, 0.3 T (tesla) for the NMR is formed, and at the space sandwiched between the two second magnets 22, a static magnetic field of 0.013T for the ESR is formed. Generally, because a large magnetic field intensity is demanded as the static magnetic field for the NMR, the first magnets 21 become large and heavy and the first magnets 21 are strongly supported by the rotation pillar 32. In addition at the static magnetic field for the ESR, a planar shape of the second magnet 22 has a shape of “C” having a certain width to keep a time period for sufficiently exciting electron spins.

As illustrated in FIG. 7, a vertically spaced distance between the two first magnets 21 is substantially the same as a vertically spaced distance between the two second magnets 22. A sample 26 is inserted into the space sandwiched between the two first magnets 21 (or the space sandwiched between the two second magnets 22), in such a state that the sample 26 is placed on a table 25. During this, gradient magnetic field coils 23 are disposed between an upper part of the sample 26 and the first magnet 21 (or the second magnets 22) above the sample 26 and between a lower part of the sample 26 (See FIG. 7) and the first magnet 21 (or the second magnets 22) below the sample 26, respectively.

Further, as illustrated in FIGS. 4 and 6, the table 25 on which the sample 26 is placed is supported by a supporting base 33, and the support base 33 is further fixed on a floor on which the base 30 is installed near the base 30. In addition, the two gradient magnetic field coils 23, which are vertically disposed, are rigidly connected to each other with a connecting member 29 as well as fixed on a part of the table 25 or the upper face of the base 30 (not shown).

Accordingly, in this embodiment, though the rotation pillar 32 rotates, which rotates the first magnets 21 and the second magnets 22, the sample 26 and the gradient magnetic field coils 23 are kept in a stationary state. In other words, when the the rotation pillar 32 rotates, the spaces, in which the static magnetic field for the NMR and the static magnetic field for the ESR are formed, cross the sample 26 and the gradient magnetic field coils 23. Conversely, the sample 26 and the gradient magnetic field coils 23 successively move (relative movement) in the static magnetic field for the NMR and the static magnetic field for the ESR.

Further, in this embodiment, an NMR resonation coil 27 and an ESR resonation coil 28 are fixed to the gradient magnetic field coils 23 or the connecting members 29. Accordingly, the NMR resonation coil 27 and the ESR resonation coil 28 are kept in stationary state though the rotation pillar 32 rotates. A resonation frequency of the ESR resonation coil 28 is 370 MHz when the static magnetic field for the ESR approximately has 0.013 T. A resonation frequency of the NMR resonation coil 27 is 12 MHz when the static magnetic field for the NMR approximately has 0.03 T.

Further, in this embodiment, to sake of convenience for the user, the table 25 on which the sample 26 is placed is movably supported by the supporting base 33 in a diameter direction of the base 30. Accordingly, the user can place the sample 26 on the table 25 in such a state that the table 25 is drawn from the space sandwiched between the first magnets 21 or the second magnets 22. Thus, the sample 26 placed on the table 25 can be inserted into the space sandwiched between the first magnets 21 or the second magnets 22.

The ESR/NMR integrated type MRI device 200 configured as mentioned above is used as an OMRI (Overhauser effect MRI) described above. More specifically, the electron spins of unpaired electrons included in the sample 26 are excited by the radio frequency signal (electromagnetic waves) radiated by the ESR resonation coil 28 while the sample 26 is relatively moving in the static magnetic field for the ESR formed by the second magnets 22. During this, nuclear spins including the unpaired electrons are excited by the Overhauser effect. Next, when the sample 26 moves (relatively moves) in the static magnetic field for the NMR formed by the first magnets 21, the sample 26 is irradiated with a radio frequency signal (electromagnetic waves) emitted by the NMR resonation coil 27 in accordance with a predetermined NMR photographing sequence. Accordingly, nuclear spins are excited as well as a gradient magnetic field is appropriately applied by the gradient magnetic field coils 23, and the NMR signal emitted from the sample 26 is received by the NMR resonation coil 27.

The NMR signal received as described above includes the resonance signal emitted from the nuclear spins excited by the Overhauser effect. Accordingly, the MRI image generated from the NMR signal includes distribution information of the unpaired electron spins excited by the Overhauser effect, i.e., the distribution information of the unpaired electron spin. Accordingly, the OMRI image can be obtained.

Further, the ESR/NMR integrated type MRI device 200 includes a control device (not shown) similar to the case of the first embodiment. The control device performs controls including a control for rotating the rotation pillar 32, i.e., a control for rotating the first magnets 21 and the second magnet 22, a control for forming the gradient magnetic fields by allowing currents through the magnetic-field gradient coil 13, a control for outputting the radio frequency signal from the NMR resonation coil 27 or the ESR resonation coil 28 and receiving the NMR signal, etc.

The ESR/NMR integrated type MRI device 200 according to this embodiment can be used as an ordinary MRI device also. For this, it is sufficient to stop rotation of the first magnets 21 and the second magnets 22 at such a location that the sample 26 locates at a substantially center of the static magnetic field for the NMR generated by the first magnets 21. In this case, an MRI image can be obtained in the state in which the sample 26 stops relative to the first magnets 21.

Further, the ESR/NMR integrated type MRI device 200 according to the present embodiment can provide an ordinary MRI image though the ESR/NMR integrated type MRI device 200 is in such a state that the first magnets 21 and the second magnets 22 are rotating. More specifically, when the high frequency signal is made not emitted by the ESR resonation coil 28 while the sample 26 is relatively moving in the static magnetic field for the ESR formed by the second magnets 22, which does not cause the Overhauser effect, an ordinary MRI image can be obtained while the sample 26 relatively moves in the static magnetic field for the NMR.

Further, in the ESR/NMR integrated type MRI device 200 according to the present embodiment, comparing the MRI image (OMRI image) of the sample 26 including the distribution information of the electron spins of the unpaired electrons with the MRI image of the sample 26 provides an MRI image of the sample 26 including the distribution information of the electron spin of the unpaired electrons.

In addition, an image displayed by superimposing the MRI image (ESRI image) of the sample 26 including only the distribution information of the electron spin of the unpaired electrons obtained as described above on an ordinary MRI image of the same sample 26, becomes an image in which the distribution information of the electron spins of the unpaired electron is displayed on the image of an ordinal MRI image also indicating a shape of of the sample 26. In addition, in this embodiment, only rotating the first magnets 21 and the second magnets 22 are continuously rotated, in which case the distribution information of the electron spins of the unpaired electrons can be continuously obtained, so that time transition of the electron spin distribution of the unpaired electron can be visualized. The time transition of the electron spins distribution of the unpaired electrons corresponds to an image representing the state of the reactive oxygen and free radicals. This promotes understanding the Redox reaction.

The ESR/NMR integrated type MRI device 200 according to the present embodiment has functions which are almost similar to those of the OMRI (integrated type of MRI) disclosed in Patent Document 2. However, in the present embodiment, because the gradient magnetic field coil 23 has a separate structure which is separated from the first magnets 21, though the first magnets 21 and the second magnets 22 rotate by rotation of the rotation pillar 32, the gradient magnetic field coil 23 does not rotate and is immovable together with the sample 26.

Accordingly, in the present embodiment, since the gradient magnetic field coil 23 does not rotate, the power cables connected to the gradient magnetic field coil 23 are never twisted. Accordingly, the connection and feeding part of the power cables to the gradient magnetic field coils 23 is provided using a simple structure. In other words, according to the present embodiment, the problem in the OMRI disclosed in Patent Document 2 can be solved.

Further, as described in the first embodiment, the separated structure in which the gradient magnetic field coil 23 is separated from the first magnet 21 cannot be introduced from the conventional idea. This is because it is supposed to be difficult to secure the homogeneity in the static magnetic field for the NMR formed by the the first magnets 21. However, the inventors of the present invention made a trial device having the separated structure in which the gradient magnetic field coil 23 is separated from the first magnets 21, independently of common knowledge described above. The device provided a preferable MRI image and OMRI image which are practically usable.

In this embodiment, a relative speed when the first magnet 21 rotates is 1 to 2 m/sec relative to the sample 26. This is because in the study of redox metabolism, it is required to obtain time transition images of an intensity distribution, i.e., a distribution of the reactive oxygen or free radicals, of the electron spins at a cycle which is as short as possible (for example, a cycle of 1 to 2 seconds).

Now, when it is assumed that the relative speed of the first magnets 21 in rotating is 1 to 2 m/sec and a length of the homogeneous region of the static magnetic field for the NMR formed by the first magnets 21 is 10 cm, a photographing sequence from when the nuclear spins are excited to when the MRI signal is obtained must be completed within tens milliseconds. In the conventional spin echo method or the conventional gradient echo method, etc, the photographing sequence becomes too long, so that the sample 26 exits the homogeneous region of the static magnetic field for the NMR before completion. of the photographing sequence.

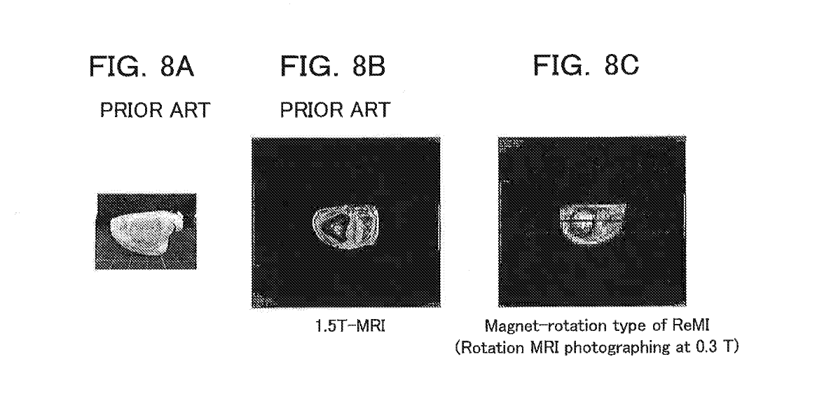

FIG. 8 is a drawing illustrating an MRI image obtained by the ESR/NMR integrated type of MRI device 200 according to the second embodiment of the present invention with reference to an MRI image obtained by a conventional MRI device. In FIG. 8, an image on the left side is a photographed image of a pig's foot used as the sample 26. An image on the center is an MRI image of a pig's foot captured by a general MRI device having a static magnetic field for the NMR of 1.5 T. An image on the right side is an MRI image of a pig's foot obtained by the ESR/NMR integrated type MRI device 200 according to the present embodiment (an intensity of the static magnetic field for the NMR: 0.3 T, the relative moving speed between the sample 26 and the gradient magnetic field coil 23: 1 m/sec).

As illustrated by FIG. 8, it is understood that a preferable MRI image can be obtained to such an extent that it can be usable for practical use even by the ESR/NMR integrated type MRI device 200 according to the present invention.

As described above, in the ESR/NMR integrated type MRI device 200, though the second magnets 22 is moved at a high speed relative to the sample 26 and the gradient magnetic field coil 23 according to the second embodiment, the preferable MRI image can be obtained. Further, because the gradient magnetic field coil 23 is rest, the connection and feeding part connected to the gradient magnetic field coil 23 can be made with a simple structure. Further, in the photographing sequence, because the relative position between the gradient magnetic field coil 23 and the sample 26 does not change, the sample can be photographed at a center of FOV without special timing adjustment for photographing.

Further, it is clear that the ESR/NMR integrated type MRI device 200 can be used as a measuring device in which the NMR signal or an NMR having a DNP (Dynamic Nuclear Polarization) effect such as the Overhauser effect is simply obtained for analysis though the ESR/NMR integrated does not obtain the MRI image or the OMRI image of the sample 26.

### DESCRIPTION OF REFERENCE SYMBOLS

11 magnet
13 magnetic-field gradient coil
15 table
16 subject person (sample)
18 cart
19 track
100 MRI device
200 ESR/NMR integrated type MRI device (MRI device)
21 first magnet
22 second magnet
23 gradient magnetic field coil
25 table
26 sample
27 NMR resonation coil
28 ESR resonation coil
29 connecting member
30 base
32 rotation pillar
33 supporting base
100 MRI device
200 ESR/NMR integrated type MRI device

1. A measurement apparatus, comprising:
a magnet forming a static magnetic field in a predetermined regional space;
a magnetic-field gradient coil applying a gradient magnetic field to the static magnetic field, the magnetic-field gradient coil so arranged to be movable relative to the magnet forming the static magnetic field; and
a resonation coil radiating a radio frequency signal that excites nuclear spins included in a sample and receiving a nuclear magnetic resonance signal caused by the nuclear spins.

2. The measurement apparatus as claimed in claim 1 wherein
the sample is irradiated with the radio frequency signal through the resonation coil and receives and obtains the nuclear magnetic resonance signal, while the magnetic-field gradient coil is relatively moving in the regional space in which the static magnetic field is formed.

3. The measurement apparatus as claimed in claim 2, wherein a magnetic resonance image of the sample is generated on the base of the obtained nuclear magnetic resonance signal.

4. The measurement apparatus as claimed in claim 1, further comprising:
a second magnet forming a second static magnetic field, which is different from the static magnetic field, in a second regional space adjacent to the regional space in which the static magnetic field is formed, wherein the magnetic-field gradient coil is arranged movable relatively to both the magnet and the second magnet;
a radio frequency signal, exciting electron spins included in the sample, is applied through the resonation coil to the sample, while the magnetic-field. gradient coil moves in the second regional space in which the second static magnetic field is formed; and
a radio frequency signal, exciting nuclear spins included in the sample, is applied through the resonation coil to the sample and receives and obtains a nuclear magnetic resonance signal, while the magnetic-field gradient coil relatively moves in the regional space in which the static magnetic field is formed.

5. The measurement apparatus as claimed in claim 4, wherein a magnetic resonance image of the sample is further generated on the basis of the obtained nuclear magnetic resonance signal.

6. The measurement apparatus as claimed in claim 4, wherein
the magnetic-field gradient coil is arranged and fixed to the pillar base having a circular pillar form; wherein
the magnet and the second magnet are so arranged to be revolutionally movable along a circumferential edge of a circular upper face of the base having the circular pillar form; wherein
the magnetic-field gradient coil relatively moves in the static magnetic field and the second magnetic field formed by the magnet and the second magnet, respectively while the magnetic and the second magnet revolves along the circumferential edge on the circular upper face of the base having the circular pillar form.

7. A measurement method, in a measurement apparatus including; a magnet forming a static magnetic field in a predetermined regional space; a magnetic-field gradient coil applying a gradient magnetic field to the static magnetic field, the magnetic-field gradient coil so arranged to be movable relatively to the magnet forming the static magnetic field; and a resonation coil radiating a radio frequency signal that excites nuclear spins included in a sample and receiving a nuclear magnetic resonance signal caused by the nuclear spins, wherein
the measurement apparatus irradiates the sample with the radio frequency signal through the resonation coil and receives and obtains a nuclear magnetic resonance signal, while the magnetic-field gradient coil is relatively moving in the regional space in which the static magnetic field is formed.

8. The measurement method as claimed in claim 7, wherein the measurement apparatus further generates a magnetic resonance image of the sample on the basis of the obtained nuclear magnetic resonance signal.

9. The measurement method. as claimed in claim 7, wherein
the measurement apparatus further includes a second magnet forming a second static magnetic field, which is different from the static magnetic field, in a second regional space adjacent to the regional space in which the static magnetic field is formed, wherein the magnetic-field gradient coil is arranged movable relatively to both the magnet and the second magnet; wherein
the measurement apparatus irradiates the sample with a radio frequency signal, exciting electron spins included in the sample, through the resonation coil to the sample, while the magnetic-field gradient coil is relatively moving in the second regional space in which the second static magnetic field is formed; and irradiates the sample with a radio frequency signal, exciting nuclear spins included in the sample, through the resonation coil and receives and obtains a nuclear magnetic resonance signal, while the magnetic-field gradient coil relatively moves in the regional space in which the static magnetic field is formed.

10. The measurement method as claimed in claim 9, wherein the measurement apparatus generates a magnetic resonance image of the sample on the basis of the obtained nuclear magnetic resonance signal.

11. The measurement method as claimed in claim 9, wherein the magnetic-field gradient coil is arranged and fixed to the a circular-pillar base; wherein
the magnet and the second magnet are so arranged to be revolutionally movable along a circumferential edge of a circular upper face of the base having a circular pillar form; wherein
the magnetic-field gradient coil relatively moves in the static magnetic field and the second magnetic field formed by the magnet and the second magnet, respectively while the magnetic-field gradient coil revolves along the circumferential edge on the circular upper face of the base having the circular pillar form.
